(19) United States
(12) Patent Application Publication
(10) Pub. No.: US 2024/0332344 A1
(43) Pub. Date: Oct. 3, 2024

(54) SEMICONDUCTOR DEVICE AND METHOD FOR MANUFACTURING SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Masaki YAMADA, Saitama Saitama (JP)

(21) Appl. No.: 18/462,222

(22) Filed: Sep. 6, 2023

(30) Foreign Application Priority Data
Mar. 27, 2023 (JP) 2023-049513

(51) Int. Cl. H01G 4/008; H01L 21/321

(52) U.S. Cl. CPC H01L 28/60; H01L 21/3212

(57) ABSTRACT

A semiconductor device according to an embodiment includes: a copper layer having a lower surface, an upper surface, a first side surface, and a second side surface, in which a first distance between the first side surface and the second side surface is larger than a second distance between the lower surface and the upper surface; a first metal layer that is in contact with the lower surface, the first side surface, and the second side surface and contains a first metal material different from copper; and a second metal layer that is in contact with the upper surface and contains a second metal material different from copper.

### CROSS-REFERENCE TO RELATED APPLICATION

This application is based upon and claims the benefit of priority from Japanese Patent Application No. 2023-049513, filed on Mar. 27, 2023, the entire contents of which are incorporated herein by reference.

### FIELD

Embodiments described herein relate generally to a semiconductor device and a method for manufacturing the semiconductor device.

### BACKGROUND

As a wiring layer of a semiconductor device, for example, a copper layer is used. By forming an electronic circuit with a copper layer having low electric resistance, a high-performance semiconductor device can be realized. In order to further reduce the electric resistance of the wiring layer and further improve the performance of the semiconductor device, it is desired to increase the thickness of the copper layer.

### BRIEF DESCRIPTION OF THE DRAWINGS

FIG. 1 is a schematic sectional view of a semiconductor device according to a first embodiment;

FIG. 2 is a schematic sectional view of the semiconductor device according to the first embodiment;

FIG. 3 is a schematic sectional view illustrating a method for manufacturing the semiconductor device according to the first embodiment;

FIG. 4 is a schematic sectional view illustrating the method for manufacturing the semiconductor device according to the first embodiment;

FIG. 5 is a schematic sectional view illustrating the method for manufacturing the semiconductor device according to the first embodiment;

FIG. 6 is a schematic sectional view illustrating the method for manufacturing the semiconductor device according to the first embodiment;

FIG. 7 is a schematic sectional view illustrating the method for manufacturing the semiconductor device according to the first embodiment;

FIG. 8 is a schematic sectional view illustrating the method for manufacturing the semiconductor device according to the first embodiment;

FIG. 9 is a schematic sectional view illustrating the method for manufacturing the semiconductor device according to the first embodiment;

FIG. 10 is a schematic sectional view of a semiconductor device of a comparative example;

FIG. 11 is an explanatory view of a problem of the semiconductor device of the comparative example;

FIG. 12 is a schematic sectional view of a semiconductor device of a modification of the first embodiment; and

FIG. 13 is a schematic sectional view of a semiconductor device according to a second embodiment.

### DETAILED DESCRIPTION

A semiconductor device according to an embodiment includes: a copper layer having a lower surface, an upper surface, a first side surface, and a second side surface, a first distance between the first side surface and the second side surface being larger than a second distance between the lower surface and the upper surface; a first metal layer in contact with the lower surface, the first side surface, and the second side surface and containing a first metal material different from copper; and a second metal layer in contact with the upper surface and containing a second metal material different from copper.

In the present specification, the same or similar members are denoted by the same reference numerals, and redundant description may be omitted.

In the present specification, in order to indicate a positional relationship of components and the like, an upward direction in the drawings may be described as “upper”, and a downward direction in the drawings may be described as “lower”. In the present specification, the concepts of “upper” and “lower” are not necessarily terms indicating the relationship with the direction of gravity.

Qualitative analysis and quantitative analysis of chemical composition of members constituting the semiconductor device in the present specification can be performed by, for example, secondary ion mass spectroscopy (SIMS) and energy dispersive X-ray spectroscopy (EDX). In addition, for measuring the thickness of the members constituting the semiconductor device, the distance between the members, and the like, for example, a scanning electron microscope (SEM) or a transmission electron microscope (TEM) can be used.

### First Embodiment

A semiconductor device according to a first embodiment includes: a copper layer having a lower surface, an upper surface, a first side surface, and a second side surface, in which a first distance between the first side surface and the second side surface is larger than a second distance between the lower surface and the upper surface; a first metal layer that is in contact with the lower surface, the first side surface, and the second side surface and contains a first metal material different from copper; and a second metal layer that is in contact with the upper surface and contains a second metal material different from copper.

The semiconductor device according to the first embodiment is an LSI 100. The LSI 100 includes a copper layer as a wiring layer.

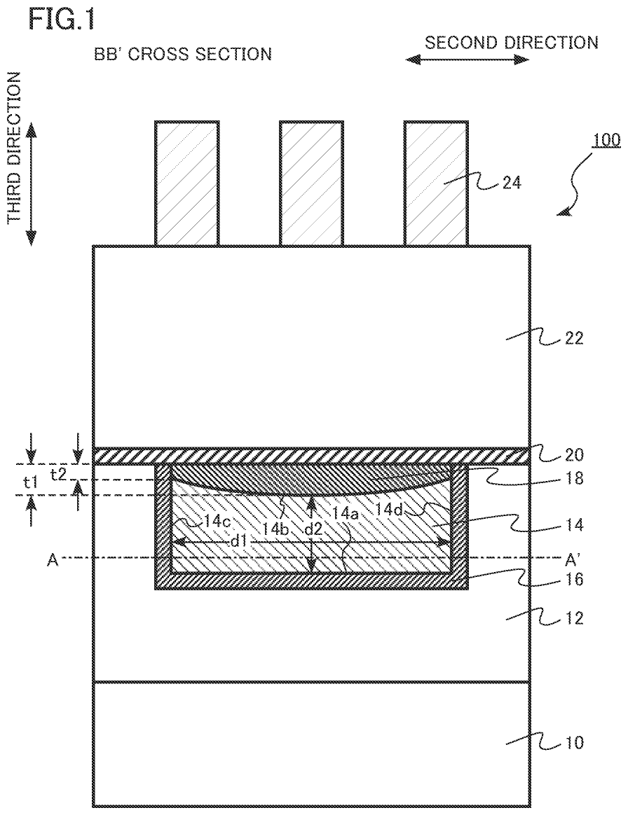

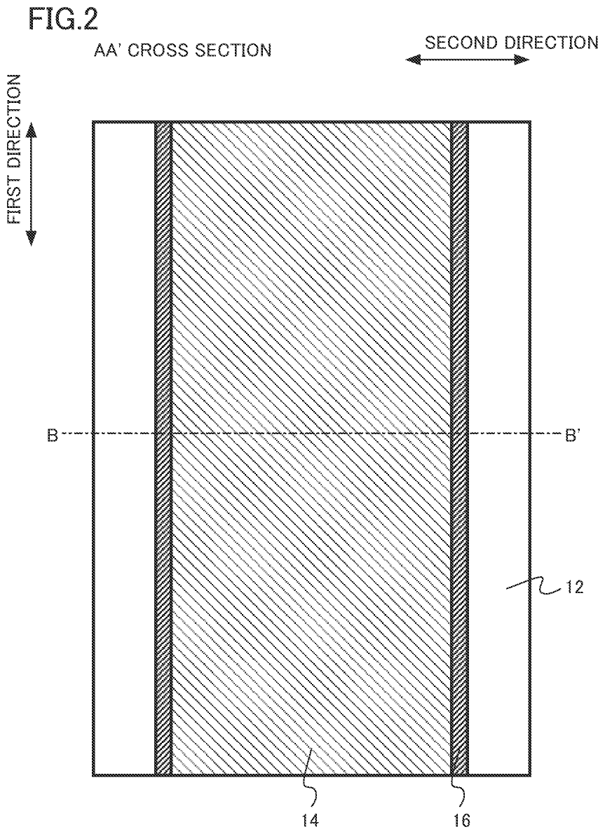

FIGS. 1 and 2 are schematic sectional views of the semiconductor device according to the first embodiment. FIG. 1 is a cross section taken along line BB′ in FIG. 2. FIG. 2 is a cross section taken along line AA′ in FIG. 1.

The LSI 100 includes a silicon substrate 10 (semiconductor substrate), a first interlayer insulating layer 12, a copper layer 14, a barrier metal layer 16 (first metal layer), a cap metal layer 18 (second metal layer), a cover insulating film 20 (insulating film), a second interlayer insulating layer 22, and upper wiring layers 24.

In the first embodiment, a first direction and a second direction are directions parallel to the surface of the silicon substrate 10. The second direction is a direction perpendicular to the first direction. A third direction is a direction perpendicular to the surface of the silicon substrate 10. The third direction is a direction perpendicular to the first direction and the second direction.

FIG. 1 is a cross section perpendicular to the first direction. FIG. 2 is a cross section perpendicular to the third direction.

The silicon substrate 10 is, for example, single crystal silicon. The silicon substrate 10 is an example of a semiconductor substrate.

The first interlayer insulating layer 12 is provided on the silicon substrate 10. The first interlayer insulating layer 12 is, for example, silicon oxide.

For example, semiconductor elements such as a transistor and a diode (not illustrated) are formed in the silicon substrate 10 and the first interlayer insulating layer 12.

The copper layer 14 is provided in the first interlayer insulating layer 12. The copper layer 14 extends in the first direction.

The copper layer 14 contains copper as a main component. The proportion of copper contained in the copper layer 14 is, for example, equal to or more than 99%.

The copper layer 14 has a lower surface 14a, an upper surface 14b, a first side surface 14c, and a second side surface 14d. The lower surface 14a faces the upper surface 14b. The first side surface 14c faces the second side surface 14d.

A first distance (d1 in FIG. 1) between the first side surface 14c and the second side surface 14d is larger than a second distance (d2 in FIG. 1) between the lower surface 14a and the upper surface 14b. The first distance d1 is, for example, equal to or more than 1.5 times and equal to or less than 50 times of the second distance d2.

The second distance d2 is, for example, equal to or more than 2 μm and equal to or less than 5 μm. The first distance d1 is, for example, equal to or more than 3 μm and equal to or less than 100 μm.

The thickness of the copper layer 14 in the third direction is equal to or more than 2 μm.

The barrier metal layer 16 is in contact with the lower surface 14a, the first side surface 14c, and the second side surface 14d of the copper layer 14. The barrier metal layer 16 is provided between the copper layer 14 and the first interlayer insulating layer 12. The barrier metal layer 16 is in contact with the first interlayer insulating layer 12.

The barrier metal layer 16 is a conductor. The barrier metal layer 16 contains the first metal material different from copper. The first metal material contains, for example, at least one material selected from the group consisting of tantalum, tantalum nitride, titanium, titanium nitride, tungsten, tungsten nitride, and titanium tungsten.

The barrier metal layer 16 is, for example, a tantalum layer, a tantalum nitride layer, a titanium layer, a titanium nitride layer, a tungsten layer, a tungsten nitride layer, or a titanium tungsten layer. The barrier metal layer 16 may have, for example, a stacked structure of a plurality of layers selected from a tantalum layer, a tantalum nitride layer, a titanium layer, a titanium nitride layer, a tungsten layer, a tungsten nitride layer, and a titanium tungsten layer.

The thickness of the barrier metal layer 16 is, for example, equal to or more than 1 nm and equal to or less than 100 nm.

The barrier metal layer 16 functions as, for example, a diffusion prevention layer of copper.

The cap metal layer 18 is in contact with the upper surface 14b of the copper layer 14. The barrier metal layer 16 is provided between the copper layer 14 and the cover insulating film 20. The cap metal layer 18 is in contact with the cover insulating film 20.

The cap metal layer 18 is a conductor. The cap metal layer 18 contains the second metal material different from copper. The second metal material contains, for example, at least one material selected from the group consisting of tantalum, tantalum nitride, titanium, titanium nitride, tungsten, tungsten nitride, and titanium tungsten. The second metal material is, for example, the same material as the first metal material.

The cap metal layer 18 is, for example, a tantalum layer, a tantalum nitride layer, a titanium layer, a titanium nitride layer, a tungsten layer, a tungsten nitride layer, or a titanium tungsten layer. The cap metal layer 18 may have, for example, a stacked structure of a plurality of layers selected from a tantalum layer, a tantalum nitride layer, a titanium layer, a titanium nitride layer, a tungsten layer, a tungsten nitride layer, and a titanium tungsten layer.

The Young's modulus of the second metal material contained in the cap metal layer 18 is higher than the Young's modulus of copper, for example. For example, the Young's moduli of titanium, tantalum, and tungsten are higher than the Young's modulus of copper.

In a cross section including the lower surface 14a, the upper surface 14b, the first side surface 14c, and the second side surface 14d, for example, the thickness (t1 in FIG. 1) of the central portion of the cap metal layer 18 is larger than the thickness (t2 in FIG. 1) of both end portions. Note that the BB′ cross section illustrated in FIG. 1 is an example of a cross section including the lower surface 14a, the upper surface 14b, the first side surface 14c, and the second side surface 14d. The thickness t1 of the central portion of the cap metal layer 18 is, for example, equal to or more than 1.2 times and equal to or less than 100 times of the thickness t2 of both end portions.

The thickness of the cap metal layer 18 is, for example, equal to or more than 1 nm and equal to or less than 100 nm. The thickness t1 of the central portion of the cap metal layer 18 is, for example, equal to or more than 1 nm and equal to or less than 100 nm. The thickness t2 of both end portions of the cap metal layer 18 is, for example, equal to or more than 0.1 nm and equal to or less than 100 nm.

Both end portions of the cap metal layer 18 are in contact with the barrier metal layer 16. In a cross section including the lower surface 14a, the upper surface 14b, the first side surface 14c, and the second side surface 14d, for example, the copper layer 14 is surrounded by the barrier metal layer 16 and the cap metal layer 18.

The cap metal layer 18 functions as, for example, a diffusion prevention layer of copper.

The cover insulating film 20 is provided on the cap metal layer 18 and the first interlayer insulating layer 12. The cover insulating film 20 is in contact with, for example, the cap metal layer 18 and the first interlayer insulating layer 12.

The cover insulating film 20 is an insulator. The cover insulating film 20 contains, for example, silicon nitride, silicon carbide, or silicon carbonitride. The cover insulating film 20 is, for example, a silicon nitride film, a silicon carbide film, or a silicon carbonitride film. The cover insulating film 20 may be, for example, a stacked film of a plurality of films selected from a silicon nitride film, a silicon carbide film, and a silicon carbonitride film.

The thickness of the cover insulating film 20 in the third direction is, for example, equal to or more than 2 nm and equal to or less than 200 nm.

The cover insulating film 20 functions as, for example, a diffusion prevention film of copper. The cover insulating film 20 can be omitted.

The second interlayer insulating layer 22 is provided on the cover insulating film 20. The second interlayer insulating layer 22 is, for example, silicon oxide.

The thickness of the second interlayer insulating layer 22 in the third direction is larger than the thickness of the cover insulating film 20 in the third direction. The thickness of the second interlayer insulating layer 22 in the third direction is, for example, equal to or more than 0.5 μm and equal to or less than 10 μm.

The relative permittivity of the second interlayer insulating layer 22 is lower than the relative permittivity of the cover insulating film 20, for example. In other words, the relative permittivity of the cover insulating film 20 is higher than the permittivity of the second interlayer insulating layer 22, for example.

The upper wiring layers 24 are provided on the second interlayer insulating layer 22. The upper wiring layers 24 extend, for example, in the first direction.

The upper wiring layer 24 is a conductor. The upper wiring layer 24 contains, for example, copper or aluminum.

Next, an example of a method for manufacturing the semiconductor device according to the first embodiment will be described. The method for manufacturing the semiconductor device according to the first embodiment is a method for manufacturing the LSI 100.

In the method for manufacturing the semiconductor device according to the first embodiment, a recess having a depth of equal to or more than 2 μm and a width larger than the depth is formed in an insulating layer, a first metal film is formed in the recess, the recess is embedded with a copper film, the copper film and the first metal film are polished by a chemical mechanical polishing method to remove the copper film and the first metal film on the insulating layer, a second metal film is formed on the copper film, the second metal film is polished by a chemical mechanical polishing method to remove the second metal film on the insulating layer, and the second metal film is left on the copper film.

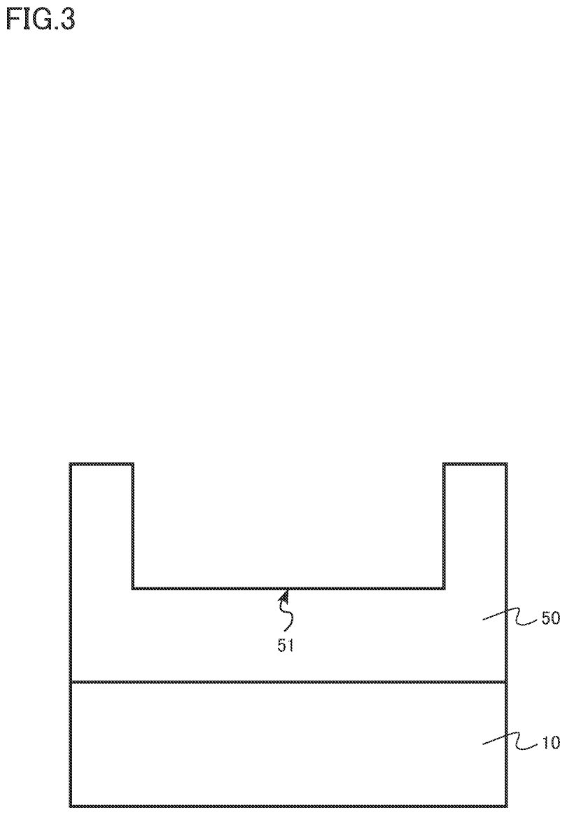

FIGS. 3, 4, 5, 6, 7, 8, and 9 are schematic sectional views illustrating the method for manufacturing the semiconductor device according to the first embodiment.

First, an element such as a transistor (not illustrated) is formed on the silicon substrate 10 using a known manufacturing method. Further, an insulating layer 50 is formed on the silicon substrate 10. The insulating layer 50 is formed by using, for example, a chemical vapor deposition method (CVD method).

The insulating layer 50 is, for example, silicon oxide. The insulating layer 50 finally becomes the first interlayer insulating layer 12.

Next, a recess 51 is formed in the insulating layer 50 (FIG. 3). The recess 51 is formed by, for example, patterning a resist by a photolithography method and a reactive ion etching method (RIE method) using the resist as a mask. The depth of the recess 51 is equal to or more than 2 μm. The width of the recess 51 is larger than the depth.

Next, a first metal film 52 is formed in the recess 51. The first metal film 52 is formed using, for example, a sputtering method.

The first metal film 52 is, for example, a stacked film of a tantalum film and a tantalum nitride film. A part of the first metal film 52 finally becomes the barrier metal layer 16.

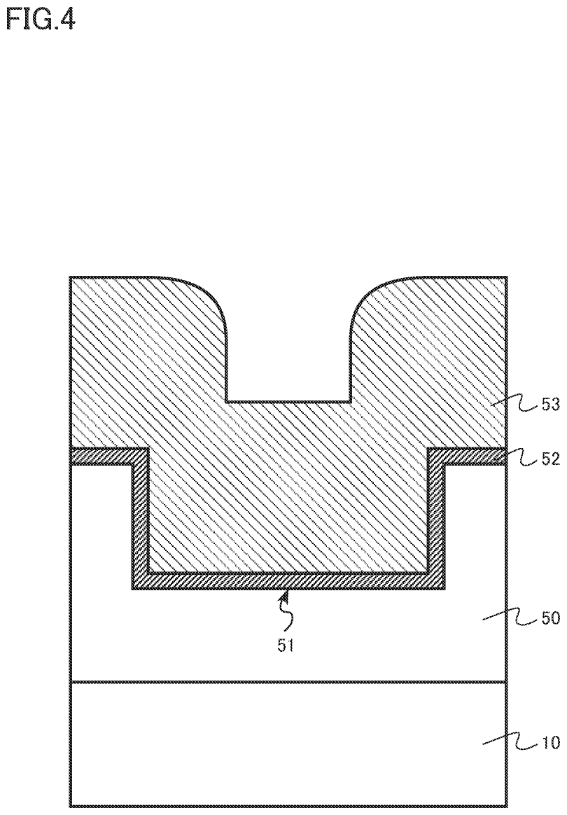

Next, the recess 51 is filled with a copper film 53 (FIG. 4). The copper film 53 is formed using, for example, a plating method. The thickness of the copper film 53 is equal to or more than 2 μm.

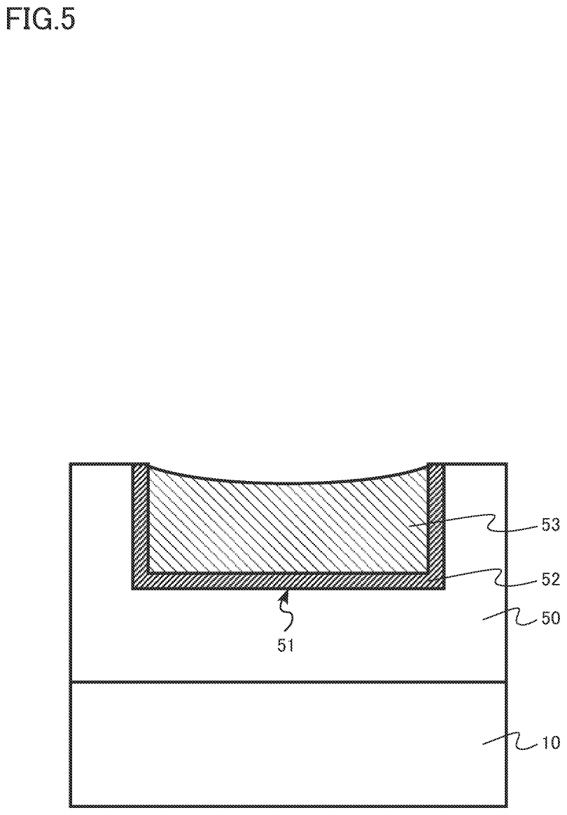

Next, the copper film 53 and the first metal film 52 are polished by a chemical mechanical polishing method (CMP method). The copper film 53 and the first metal film 52 on the insulating layer 50 are removed by polishing the copper film 53 and the first metal film 52 by a CMP method (FIG. 5).

When the copper film 53 and the first metal film 52 are polished by the CMP method, the upper surface of the copper film 53 in the recess 51 has a recessed shape. When the copper film 53 and the first metal film 52 are polished by the CMP method, so-called dishing occurs.

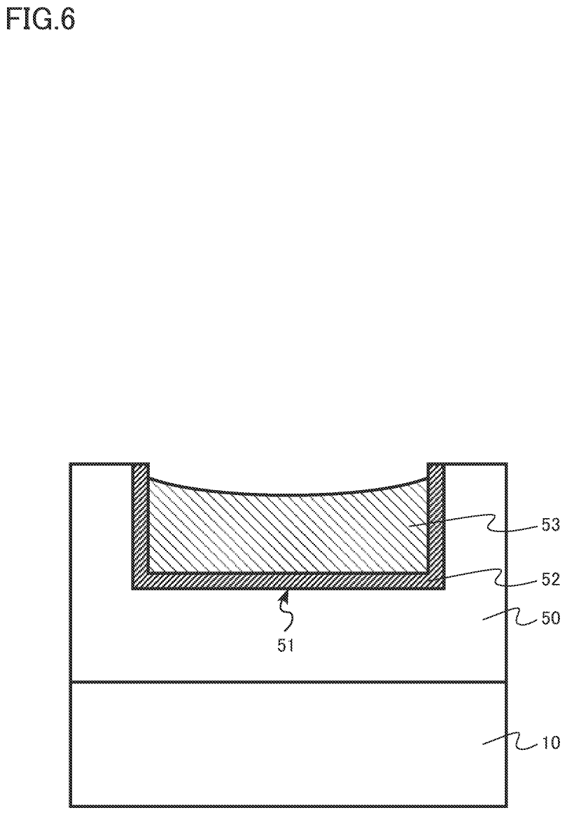

Next, a part of the upper surface of the copper film 53 is removed (FIG. 6). By removing a part of the upper surface of the copper film 53, the upper surface of the copper film 53 is lowered from the upper surface of the insulating layer 50.

A part of the upper surface of the copper film 53 is removed by, for example, a wet etching method. For example, the copper film 53 is etched using a solution containing hydrogen peroxide and hydrochloric acid.

Note that the step of etching a part of the upper surface of the copper film 53 can be omitted.

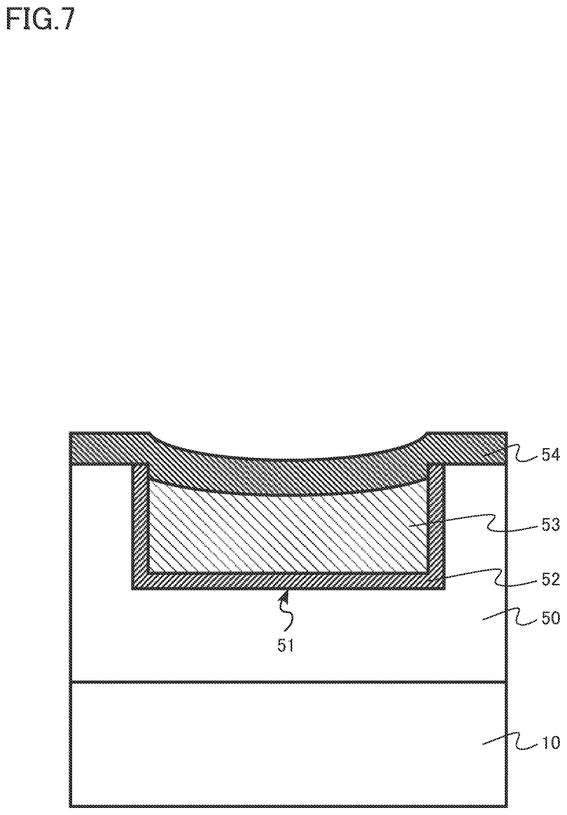

Next, a second metal film 54 is formed on the copper film 53 (FIG. 7). The second metal film 54 is formed using, for example, a sputtering method.

The second metal film 54 is, for example, a stacked film of a tantalum film and a tantalum nitride film. A part of the second metal film 54 finally becomes the cap metal layer 18.

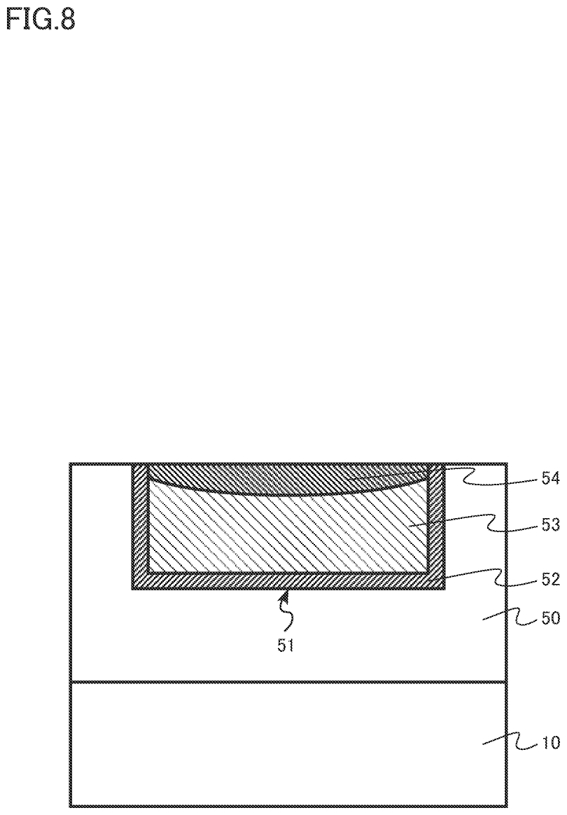

Next, the second metal film 54 is polished by a CMP method. The second metal film 54 on the insulating layer 50 is removed by polishing the second metal film 54 by the CMP method. The second metal film 54 is polished by the CMP method to leave the second metal film 54 on the copper film 53 (FIG. 8).

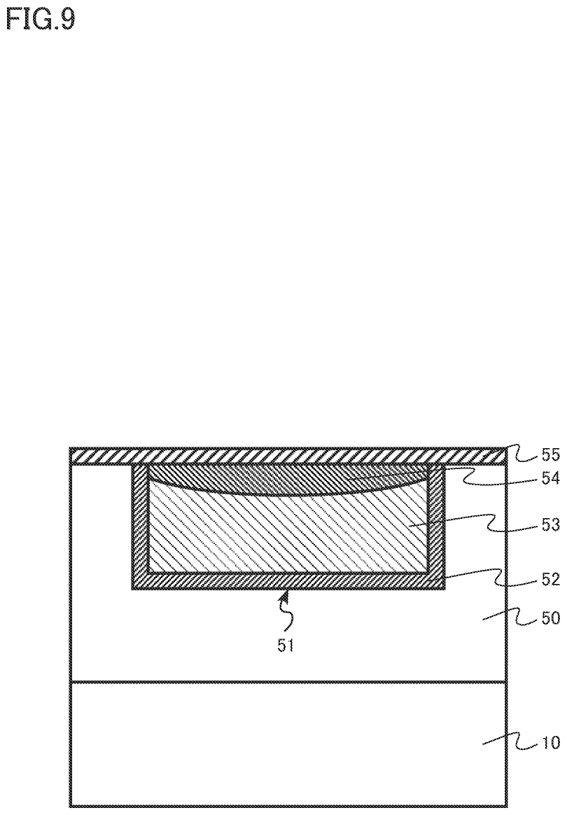

Next, a first insulating film 55 is formed on the second metal film 54 (FIG. 9). The first insulating film 55 is formed by, for example, a CVD method. The first insulating film 55 is formed using, for example, a plasma CVD method at a deposition temperature of equal to or more than 250° C.

The first insulating film 55 is, for example, a silicon nitride film, a silicon carbide film, or a silicon carbonitride film. The first insulating film 55 finally becomes the cover insulating film 20. Note that the formation of the first insulating film 55 can be omitted.

Thereafter, the upper wiring layers 24 and the second interlayer insulating layer 22 are formed on the cover insulating film 20 using a known process technique.

The LSI 100 illustrated in FIGS. 1 and 2 is formed by the above manufacturing method.

Next, the functions and effects of the semiconductor device and the method for manufacturing the semiconductor device according to the first embodiment will be described.

A copper layer is used as a wiring layer of a semiconductor device. By forming an electronic circuit with a copper layer having low electric resistance, a high-performance semiconductor device can be realized. In order to further reduce the electric resistance of the wiring layer and further improve the performance of the semiconductor device, it is conceivable to increase the thickness of the copper layer.

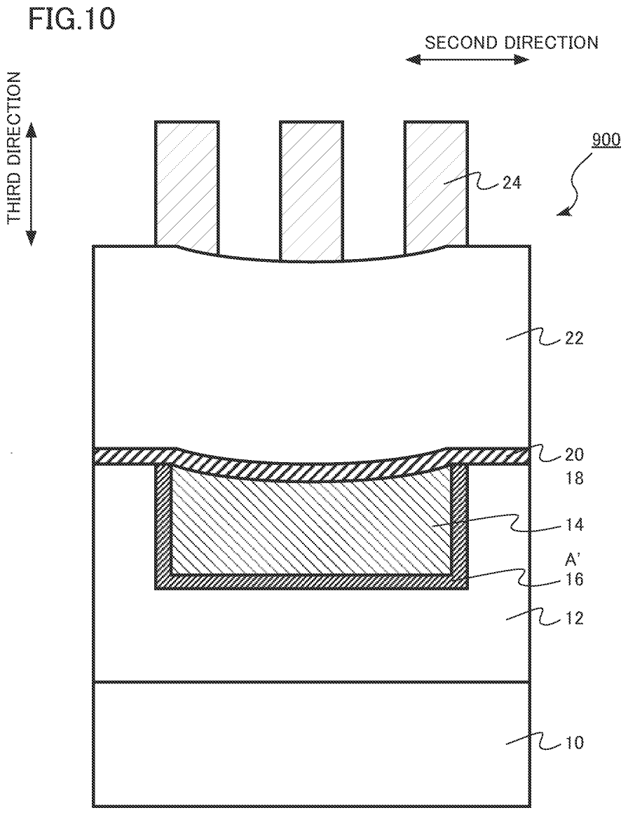

FIG. 10 is a schematic sectional view of a semiconductor device of a comparative example. The semiconductor device of the comparative example is an LSI 900.

Similarly to the LSI 100 of the first embodiment, the LSI 900 includes a silicon substrate 10 (semiconductor substrate), a first interlayer insulating layer 12, a copper layer 14, a barrier metal layer 16 (first metal layer), a cover insulating film 20 (insulating film), a second interlayer insulating layer 22, and upper wiring layers 24. The thickness of the copper layer 14 in the third direction is as large as 2 μm or more, similarly to the LSI 100 of the first embodiment.

The LSI 900 is different from the LSI 100 of the first embodiment in not including the cap metal layer 18 (second metal layer).

Since the LSI 900 does not include the cap metal layer 18, the recessed shape when the copper layer 14 is formed using the CMP method is reflected on the upper surface of the cover insulating film 20 on the copper layer 14 and the upper surface of the second interlayer insulating layer 22.

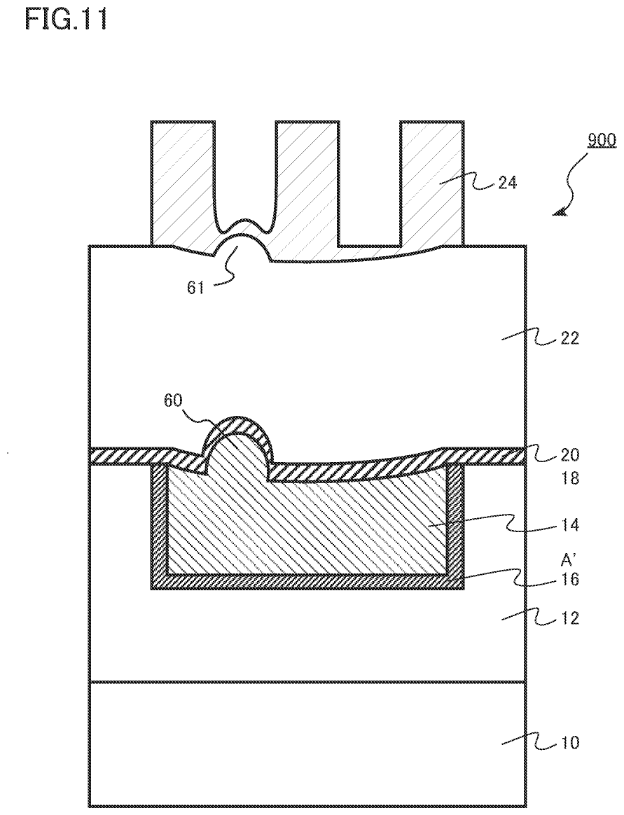

FIG. 11 is an explanatory view of a problem of the semiconductor device of the comparative example. FIG. 11 is a view corresponding to FIG. 10.

Since the LSI 900 of the comparative example does not include the cap metal layer 18, the recessed shape when the copper layer 14 is formed using the CMP method is reflected on the upper surface of the second interlayer insulating layer 22. For example, the metal material remains in the recessed portion of the upper surface of the second interlayer insulating layer 22 at the time of patterning of the upper wiring layer 24, and there is a possibility that a short circuit failure occurs in the adjacent upper wiring layer 24.

In addition, since the LSI 900 of the comparative example does not include the cap metal layer 18, a hillock 60 having a convex shape may grow when the cover insulating film 20 is formed on the copper layer 14. It is considered that the hillock 60 is generated by plastic deformation of the copper layer 14 due to compressive stress generated by temperature rise when the cover insulating film 20 is formed. In particular, when the film formation temperature at the time of forming the cover insulating film 20 is equal to or more than 250° C., the generation of the hillock 60 becomes apparent.

When the hillock 60 is generated on the upper surface of the copper layer 14, for example, as illustrated in FIG. 11, a convex shape 61 on which the convex shape of the hillock 60 is reflected is formed on the upper surface of the second interlayer insulating layer 22. For example, due to the convex shape 61 of the upper surface of the second interlayer insulating layer 22, the pattern of the upper wiring layer 24 may collapse, and a short circuit failure may occur in the adjacent upper wiring layer 24.

Furthermore, for example, a case will be considered in which the convex shape 61 on which the convex shape of the hillock 60 is reflected is formed on the upper surface of the second interlayer insulating layer 22, and a pad electrode is formed on the convex shape 61. For example, the convex shape is also reflected on the pad electrode. For example, when a probe needle for product inspection is brought into contact with the pad electrode, stress applied to the convex shape may cause cracks in the second interlayer insulating layer 22. In addition, for example, when the bonding wire is connected to the pad electrode, stress applied to the convex shape may cause cracks in the second interlayer insulating layer 22.

For example, a case of forming a contact structure connecting the copper layer 14 and the upper wiring layer 24 on the hillock 60 will be considered. When the hillock 60 is generated on the upper surface of the copper layer 14, coverage failure of the barrier metal layer used for the contact structure may occur. When coverage failure of the barrier metal layer occurs, for example, copper is diffused from the copper layer 14 to the metal layer forming the contact structure, and conduction failure of the contact structure may occur.

In addition, when the hillock 60 is generated on the upper surface of the copper layer 14, for example, as illustrated in FIG. 11, step coverage of the cover insulating film 20 on the hillock 60 is deteriorated. Therefore, for example, when the metal layer on the hillock 60 formed on the cover insulating film 20 is removed by etching, the cover insulating film 20 may disappear, and copper may scatter from the copper layer 14. The scattered copper may cause, for example, a short circuit failure between conductive layers.

The LSI 100 of the first embodiment includes a cap metal layer 18 on the copper layer 14. The cap metal layer 18 fills the recessed shape when the copper layer 14 is formed using the CMP method. Therefore, the upper surface of the second interlayer insulating layer 22 becomes flat. Therefore, short circuit failures in the upper wiring layer 24 are reduced.

In addition, the cap metal layer 18 suppresses the generation of the hillock 60 when the cover insulating film 20 is formed on the copper layer 14. By providing the cap metal layer 18 on the copper layer 14, plastic deformation of the copper layer 14 is suppressed.

From the viewpoint of suppressing the generation of the hillock 60, the Young's modulus of the second metal material contained in the cap metal layer 18 is preferably higher than the Young's modulus of copper. Therefore, the second metal material contained in the cap metal layer 18 is preferably titanium, tantalum, or tungsten having a Young's modulus higher than the Young's modulus of copper.

From the viewpoint of suppressing the generation of the hillock 60, both end portions of the cap metal layer 18 are preferably in contact with the barrier metal layer 16. In other words, in a cross section including the lower surface 14a, the upper surface 14b, the first side surface 14c, and the second side surface 14d, the copper layer 14 is preferably surrounded by the barrier metal layer 16 and the cap metal layer 18. Since the copper layer 14 is surrounded by the barrier metal layer 16 and the cap metal layer 18, plastic deformation of the copper layer 14 is suppressed.

In a cross section including the lower surface 14a, the upper surface 14b, the first side surface 14c, and the second side surface 14d, the thickness (t1 in FIG. 1) of the central portion of the cap metal layer 18 is preferably larger than the thickness (t2 in FIG. 1) of both end portions. For example, when the thickness t2 of both end portions is thin, the thickness of both end portions of the copper layer 14 increases, and the electrical resistance of the copper layer 14 reduces.

In addition, since the thickness t1 of the central portion is larger than the thickness t2 of both end portions, the flatness of the upper surface of the cap metal layer 18 is improved.

According to the method for manufacturing the LSI 100 of the first embodiment, by forming the cap metal layer 18 on the copper layer 14, the flatness of the surface of the layer formed on the copper layer 14 is improved. In addition, the generation of the hillock 60 of the copper layer 14 can be suppressed.

According to the LSI 100 and the method for manufacturing the same according to the first embodiment, the occurrence of failures due to the formation of a thick copper layer is suppressed. Therefore, the high-performance LSI 100 in which the electrical resistance of the wiring layer is reduced can be realized.

### (Modification)

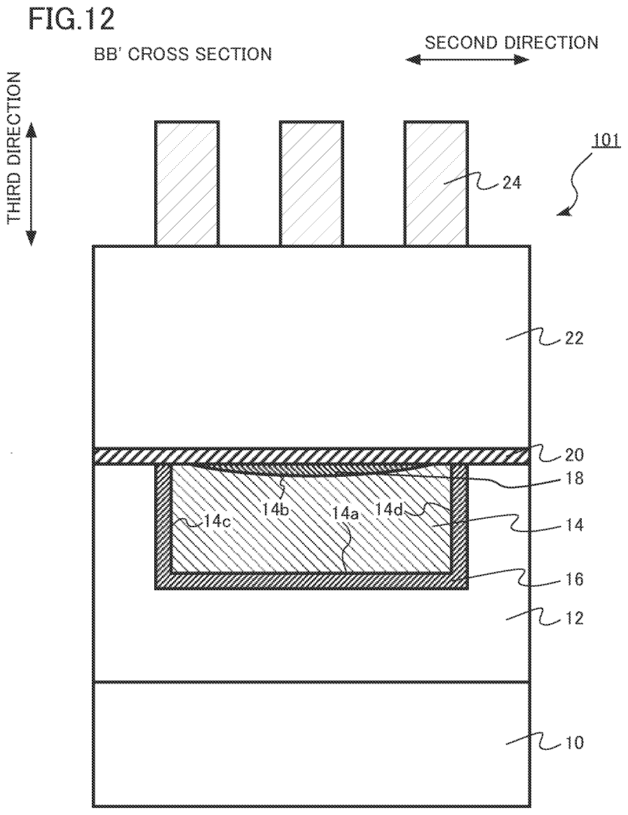

FIG. 12 is a schematic sectional view of a semiconductor device of a modification of the first embodiment. FIG. 12 is a view corresponding to FIG. 1 of the first embodiment.

The semiconductor device according to the modification of the first embodiment is an LSI 101. The LSI 101 is different from the LSI 100 of the first embodiment in that both end portions of the cap metal layer 18 are separated from the barrier metal layer 16.

According to the LSI 101 of the modification, for example, the thickness of both end portions of the copper layer 14 increases, and the electrical resistance of the copper layer 14 reduces.

As described above, according to the first embodiment and the modification, it is possible to realize a high-performance semiconductor device having a thick copper layer and a method for manufacturing the semiconductor device.

### Second Embodiment

A semiconductor device according to a second embodiment is different from the semiconductor device according to the first embodiment in that the semiconductor device further includes a capacitor insulating film provided on a second metal layer and a capacitor upper electrode provided on the capacitor insulating film, and a copper layer is a capacitor lower electrode. A method for manufacturing the semiconductor device according to the second embodiment is different from the method for manufacturing the semiconductor device according to the first embodiment in that after a second metal film on an insulating layer is removed and the second metal film is left on a copper film, a capacitor insulating film is further formed on the second metal film, and a capacitor upper electrode is further formed on the capacitor insulating film. Hereinafter, a part of the description overlapping with that of the first embodiment may be omitted.

The semiconductor device according to the second embodiment is an analog-digital mixed LSI 200. In the analog-digital mixed LSI 200, an analog LSI and a digital LSI are mixed on the same semiconductor chip. The analog-digital mixed LSI 200 includes metal multilayer wiring and a metal-insulator-metal capacitor (MIM capacitor).

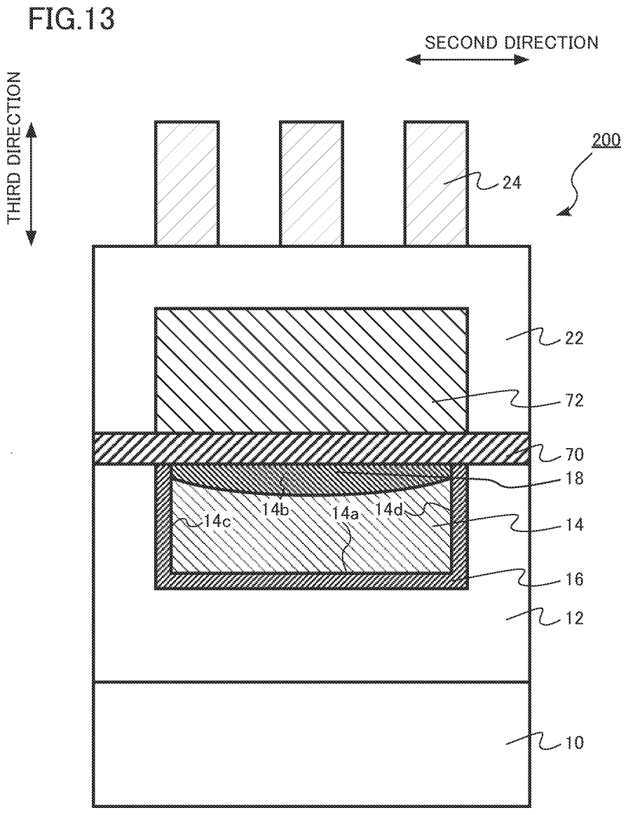

FIG. 13 is a schematic sectional view of the semiconductor device according to the second embodiment.

The analog-digital mixed LSI 200 includes a silicon substrate 10 (semiconductor substrate), a first interlayer insulating layer 12, a copper layer 14, a barrier metal layer 16 (first metal layer), a cap metal layer 18 (second metal layer), a second interlayer insulating layer 22, a capacitor insulating film 70, a capacitor upper electrode 72, and upper wiring layers 24.

For example, semiconductor elements such as a transistor and a diode (not illustrated) are formed in the silicon substrate 10 and the first interlayer insulating layer 12.

The copper layer 14, the barrier metal layer 16, the cap metal layer 18, the capacitor insulating film 70, and the capacitor upper electrode 72 constitute a MIM capacitor.

The copper layer 14, the barrier metal layer 16, and the cap metal layer 18 are lower electrodes of the MIM capacitor.

The capacitor insulating film 70 is provided on the capacitor lower electrode. The capacitor insulating film 70 is provided on the cap metal layer 18. The capacitor insulating film 70 is in contact with the cap metal layer 18.

The capacitor insulating film 70 is, for example, silicon nitride.

The capacitor upper electrode 72 is provided on the capacitor insulating film 70. The capacitor upper electrode 72 is in contact with the capacitor insulating film 70.

The capacitor upper electrode 72 is a conductor. The capacitor upper electrode 72 is, for example, metal. The capacitor upper electrode 72 is, for example, tantalum, titanium, tantalum nitride, titanium nitride, tungsten nitride, or tungsten titanium.

In the method for manufacturing the analog-digital mixed LSI 200 according to the second embodiment, a second metal film 54 is polished by the CMP method as in the method for manufacturing the first embodiment. The second metal film 54 on an insulating layer 50 is removed by polishing the second metal film 54 by the CMP method. The second metal film 54 is polished by the CMP method to leave the second metal film 54 on the copper film 53 (FIG. 8).

Thereafter, the capacitor insulating film 70 is formed on the second metal film 54. The capacitor insulating film 70 is formed by, for example, the CVD method.

Thereafter, the capacitor upper electrode 72 is formed on the capacitor insulating film 70. The capacitor upper electrode 72 is formed by, for example, a CVD method.

Thereafter, the upper wiring layers 24 and the second interlayer insulating layer 22 are formed on the cover insulating film 20 using a known process technique.

The analog-digital mixed LSI 200 illustrated in FIG. 13 is formed by the above manufacturing method.

The analog-digital mixed LSI 200 of the second embodiment includes a cap metal layer 18 on the copper layer 14. The cap metal layer 18 fills the recessed shape when the copper layer 14 is formed by the CMP method. Therefore, the flatness of the surface of the layer formed on the copper layer 14 is improved. Therefore, the occurrence of failures due to the recessed shape when the copper layer 14 is formed by the CMP method is suppressed.

The analog-digital mixed LSI 200 of the second embodiment includes the cap metal layer 18 on the copper layer 14. Therefore, the occurrence of a hillock of the copper layer 14 can be suppressed. Therefore, the occurrence of failures due to the hillock of the copper layer 14 is suppressed. For example, step coverage of the capacitor insulating film 70 formed on the hillock is deteriorated, and occurrence of a short circuit failure between the capacitor lower electrode and the capacitor upper electrode 72 is suppressed.

According to the analog-digital mixed LSI 200 and the method for manufacturing the same according to the second embodiment, the occurrence of failures due to the formation of a thick copper layer is suppressed. Therefore, the high-performance analog-digital mixed LSI 200 in which the electrical resistance of the wiring layer is reduced can be realized.

As described above, according to the second embodiment, it is possible to realize a high-performance semiconductor device having a thick copper layer and a method for manufacturing the semiconductor device.

While certain embodiments have been described, these embodiments have been presented by way of example only, and are not intended to limit the scope of the inventions. Indeed, the semiconductor device and the method for manufacturing the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a copper layer having a lower surface, an upper surface, a first side surface, and a second side surface, a first distance between the first side surface and the second side surface being larger than a second distance between the lower surface and the upper surface;
a first metal layer in contact with the lower surface, the first side surface, and the second side surface and containing a first metal material different from copper; and
a second metal layer in contact with the upper surface and containing a second metal material different from copper.

2. The semiconductor device according to claim 1, wherein the copper layer is surrounded by the first metal layer and the second metal layer in a cross section including the lower surface, the upper surface, the first side surface, and the second side surface.

3. The semiconductor device according to claim 1, wherein the second distance is equal to or more than 2 μm.

4. The semiconductor device according to claim 1, wherein a Young's modulus of the second metal material is larger than a Young's modulus of copper.

5. The semiconductor device according to claim 1, wherein the first metal material and the second metal material are same metal material.

6. The semiconductor device according to claim 1, wherein the first metal material includes at least one material selected from the group consisting of tantalum, tantalum nitride, titanium, titanium nitride, tungsten, tungsten nitride, and titanium tungsten.

7. The semiconductor device according to claim 1, wherein the second metal material includes at least one material selected from the group consisting of tantalum, tantalum nitride, titanium, titanium nitride, tungsten, tungsten nitride, and titanium tungsten.

8. The semiconductor device according to claim 1, wherein a thickness of a central portion of the second metal layer is larger than a thickness of both end portions in a cross section including the lower surface, the upper surface, the first side surface, and the second side surface.

9. The semiconductor device according to claim 1, further comprising an insulating film provided on the second metal layer and containing silicon nitride, silicon carbide, or silicon carbonitride.

10. The semiconductor device according to claim 1, further comprising:
a capacitor insulating film provided on the second metal layer; and
a capacitor upper electrode provided on the capacitor insulating film,
wherein the copper layer is a capacitor lower electrode.

11. A method for manufacturing a semiconductor device, the method comprising:
forming a recess having a depth of equal to or more than 2 μm and a width larger than the depth in an insulating layer;
forming a first metal film in the recess;
embedding the recess with a copper film;
removing the copper film and the first metal film on the insulating layer by polishing the copper film and the first metal film by a chemical mechanical polishing method;
forming a second metal film on the copper film; and
removing the second metal film on the insulating layer and leaving the second metal film on the copper film by polishing the second metal film by a chemical mechanical polishing method.

12. The method for manufacturing a semiconductor device according to claim 11, further comprising:
removing a part of the copper film before the forming the second metal film and after the removing the copper film and the first metal film on the insulating layer.

13. The method for manufacturing a semiconductor device according to claim 11, further comprising:
forming a first insulating film on the second metal film at a film formation temperature of equal to or more than 250° C. after the removing the second metal film on the insulating layer.

14. The method for manufacturing a semiconductor device according to claim 11, further comprising:
forming a capacitor insulating film on the second metal film after the removing the second metal film on the insulating layer and leaving the second metal film on the copper film; and
forming a capacitor upper electrode on the capacitor insulating film.
